(19) United States
(12) Patent Application Publication
(10) Pub. No.: US 2022/0357782 A1
(43) Pub. Date: Nov. 10, 2022

(54) EXTERNAL AUDIO DEVICE AND METHOD OF OPERATING THE SAME CAPABLE OF REDUCING POWER CONSUMPTION

(71) Applicant: Realtek Semiconductor Corp., HsinChu (TW)

(72) Inventors: Ko-Wei Chen, HsinChu (TW); Li-Wei Huang, HsinChu (TW); Shu-Yeh Chiu, HsinChu (TW); Sheng-Nan Chiu, HsinChu (TW)

(73) Assignee: Realtek Semiconductor Corp., HsinChu (TW)

(21) Appl. No.: 17/735,136

(22) Filed: May 3, 2022

(30) Foreign Application Priority Data
May 6, 2021 (TW) 110116384

(51) Int. Cl. G06F 1/26; H04R 3/00; G06F 1/3215

(52) U.S. Cl. CPC G06F 1/266; H04R 3/00; G06F 1/3215; H04R 2420/09; G06F 2213/0042; H03M 1/66

(57) ABSTRACT

An external audio device includes a USB (Universal Serial Bus) plug, an audio socket, a USB communication circuit, an audio socket detection circuit, a first power circuit, a second power circuit, and a control circuit. The USB communication circuit establishes a connection with a computer device coupled to the USB plug according to the communication protocol of USB. The audio socket detection circuit detects a plug-in state of the audio socket. The first power circuit generates a second power to the USB communication circuit according to a first power received from the USB plug. The second power circuit generates a third power to the audio socket detection circuit according to the first power. The control circuit enables or disables the first power circuit according to the plug-in state of the audio socket.

### BACKGROUND OF THE INVENTION

### 1. Field of the Invention

The invention relates to an external audio device, in particular to an external audio device capable of adjust power supply according to the plug-in state of the audio socket.

### 2. Description of the Prior Art

In order to simplify the mechanism of the electronic device and make the design of the electronic device more flexible, manufacturers of the electronic device often try to reduce the external sockets on the electronic device. For example, today's mobile devices often use a universal serial bus interface as a charging power interface, and the universal serial bus interface can also be used as an interface for an external headset or external microphone.

Since the common headsets on the market are with 3.5 mm audio plugs, users must use an audio adapter to connect a headset with a 3.5 mm audio plug to a universal serial bus interface on the mobile device. In this case, the audio adapter needs to convert audio files of different formats, and the mobile device will provide the required power to the audio adapter through the universal serial bus interface. In the prior art, when the audio adapter is plugged into the universal serial bus interface on the mobile device, the mobile device will continue to provide power to the audio adapter even if the headset is not connected to the audio adapter to maintain communications between the two. Therefore, mobile devices often waste too much power and cause inconvenience to users.

### SUMMARY OF THE INVENTION

An embodiment discloses an external audio device comprising a USB (Universal Serial Bus) plug, an audio socket, a USB communication circuit, an audio socket detection circuit, a first power circuit, a second power circuit, and a control circuit. The USB plug is configured to couple with a computer device. The first audio socket is configured to couple to a headset or a microphone. The USB communication circuit is configured to establish a connection with the computer device according to a USB communication protocol. The audio socket detection circuit is configured to detect a plug-in state of the first audio socket. The first power circuit is configured to generate a second power to the USB communication circuit according to a first power received from the USB plug. The second power circuit is configured to generate a third power to the audio socket detection circuit according to the first power. The control circuit is configured to enable or disable the first power circuit according to at least the plug-in state of the first audio socket.

Another embodiment discloses a method of operating an external audio device. The external audio device comprises a USB (Universal Serial Bus) plug, a first audio socket, a USB communication circuit, an audio socket detection circuit, a first power supply circuit, a second power supply circuit, and a control circuit. The method comprises the first power circuit generating a second power to the USB communication circuit according to a first power received by the USB plug, the second power circuit generating a third power to the audio socket detection circuit according to the first power, the audio socket detection circuit detecting a plug-in state of the first audio socket, and the control circuit enabling or disabling the first power circuit according to at least the plug-in state of the first audio socket.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an external audio device according to an embodiment of the present invention.

FIG. 2 is a schematic diagram of an external audio device according to another embodiment of the present invention.

FIG. 3 is a flowchart of a method for operating the external audio device in FIG. 1 according to an embodiment of the present invention.

### DETAILED DESCRIPTION

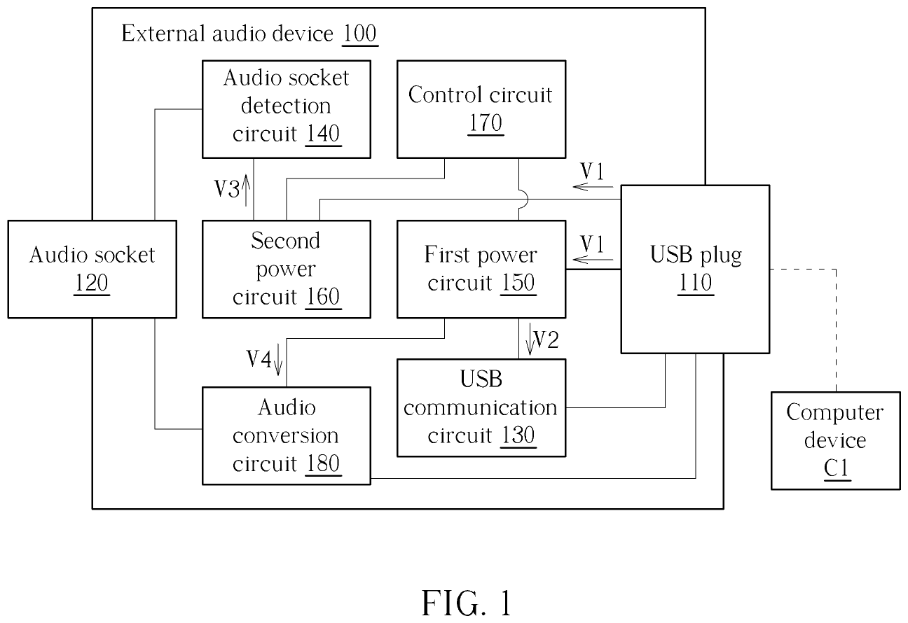

FIG. 1 is a schematic diagram of an external audio device 100 according to an embodiment of the present invention. The external audio device 100 comprises a universal serial bus (USB) plug 110, an audio socket 120, a universal serial bus communication circuit 130, an audio socket detection circuit 140, a first power circuit 150, a second power circuit 160, and a control circuit 170.

In some embodiments, the universal serial bus plug 110 can be coupled to the computer device C1, which can be, for example, but not limited to, a mobile phone, a tablet computer, or a notebook computer. The universal serial bus plug 110 may be, for example, but not limited to, a type-C plug regulated by the universal serial bus.

The audio socket 120 may be coupled with a headset or a microphone, and the audio socket 120 may be, for example, but not limited to, a 3.5 mm audio socket. In other words, through the external audio device 100, the computer device C1 can use a headset or microphone with a 3.5 mm audio plug as an audio output or input external device.

The universal serial bus communication circuit 130 can establish a connection with the computer device C1 according to the universal serial bus communication standard. In some embodiments, when the universal serial bus communication circuit 130 establishes a connection with the computer device C1, the computer device C1 can identify the external audio device 100, and can control the universal serial bus communication circuit 130 according to the human interface device (HID) standard defined by the universal serial bus.

In some embodiments, the external audio device 100 is powered by the computer device C1. For example, the computer device C1 can transmit the first power V1 to the external audio device 100 through the universal serial bus plug 110, and the first power circuit 150 can generate a second power V2 to the universal serial bus communication circuit 130 according to a first power V1 received by the universal serial bus plug 110.

In addition, the audio socket detection circuit 140 can detect the plug-in state of the audio socket 120, that is, the audio socket detection circuit 140 can determine whether the audio socket 120 is in an inserted state or an unplugged state. In some embodiments, the second power circuit 160 can generate a third power V3 to the audio socket detection circuit 140 according to the first power V1.

In some embodiments, in order to prevent the universal serial bus communication circuit 130 from unnecessarily wasting the power of the computer device C1 to maintain the connection with the computer device C1 when the audio socket 120 is not coupled to a device such as a headset or a microphone, the control circuit 170 can enable or disable the first power circuit 150 according to the plug-in state of the audio socket 120.

For example, when the external audio device 100 is not powered on and can receive the first power V1 through the universal serial bus plug 110, the control circuit 170 may first enable the first power circuit 150 and the second power circuit 160. At this time, the external audio device 100 can establish a connection with the computer device C1 through the universal serial bus communication circuit 130, and can detect the plug-in state of the audio socket 120 through the audio socket detection circuit 140.

Then, if the audio socket detection circuit 140 detects that the audio socket 120 is not plugged in, it means that the user is not ready to use an external earphone or microphone as the output or input device of the computer device C1. At this time, the control circuit 170 will disable the first power circuit 150 to cut off the connection with the computer device C1 to save power.

However, when the audio socket detection circuit 140 detects that the audio socket 120 is plugged in, the control circuit 170 will continue enabling or re-enable the first power circuit 150 so that the universal serial bus communication circuit 130 can continue or re-establish connection with the computer device C1.

In addition, to ensure that the audio socket detection circuit 140 can detect the plugged in state of the audio socket 120 in real time, the control circuit 170 can keep the second power circuit 160 enabled regardless if the audio socket detection circuit 140 has detected that the audio socket 120 is not plugged in or is plugged in.

In FIG. 1, the external audio device 100 may further comprise an audio conversion circuit 180. The audio conversion circuit 180 can convert the digital audio signal from the computer device C1 into an analog audio signal, and can also convert the analog audio signal from a microphone into a digital audio signal. In this case, the first power circuit 150 can also generate the fourth power V4 required by the audio conversion circuit 180. Since the audio conversion circuit 180 and the universal serial bus communication circuit 130 mainly operate when the audio socket 120 is plugged in, and can stop operating when the audio socket 120 is not plugged in, they can be powered by the first power circuit 150 and controlled by the control circuit 170.

In the embodiment of FIG. 1, although the first power circuit 150 and the second power circuit 160 are represented by two independent functional blocks, in some embodiments, the first power circuit 150 and the second power circuit 160 may share some of the circuits, and the first power circuit 150 and the second power circuit 160 may each comprise a plurality of voltage regulators and/or transformers according to the requirements of the system.

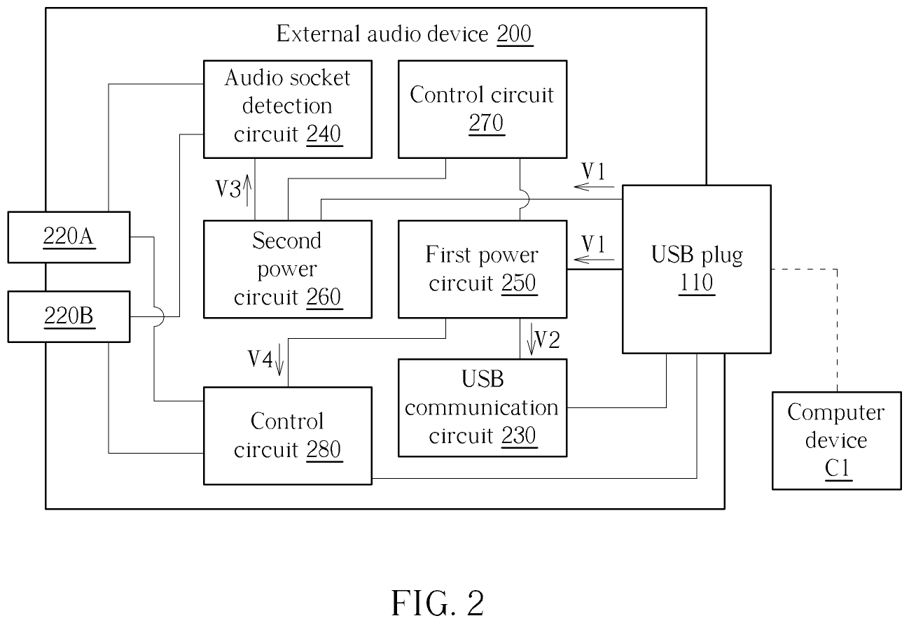

FIG. 2 is a schematic diagram of an external audio device 200 according to another embodiment of the present invention. The external audio device 200 and the external audio device 100 may have similar structures and operate according to similar principles. However, the external audio device 200 may comprise audio sockets 220A and 220B. In some embodiments, the audio socket 220A can be used to couple with a headset, and the audio socket 220B can be used to couple with a microphone. However, the present invention is not limited to this. In some other embodiments, the audio sockets 220A and 220B can both be coupled with headsets or microphones.

In the external audio device 200, the audio socket detection circuit 240 can detect the plug-in state of the audio sockets 220A and 220B, and the control circuit 270 can enable or disable the first power circuit 250 according to the plug-in states of the audio sockets 220A and 220B. For example, when the audio socket detection circuit 240 detects that the audio socket 220A and/or the audio socket 220B is plugged in, the control circuit 270 can enable the first power circuit 250. At this time, the universal serial bus communication circuit 230 and the audio conversion circuit 280 can function normally. When the audio socket detection circuit 240 detects that the audio sockets 220A and 220B are not plugged in, the control circuit 270 can disable the first power circuit 250. At this time, the universal serial bus communication circuit 230 and the audio conversion circuit 280 will stop functioning.

In addition, to ensure that the audio socket detection circuit 240 can detect the plug-in state of the audio sockets 220A and 220B in real time, the control circuit 270 can keep the second power circuit 260 enabled.

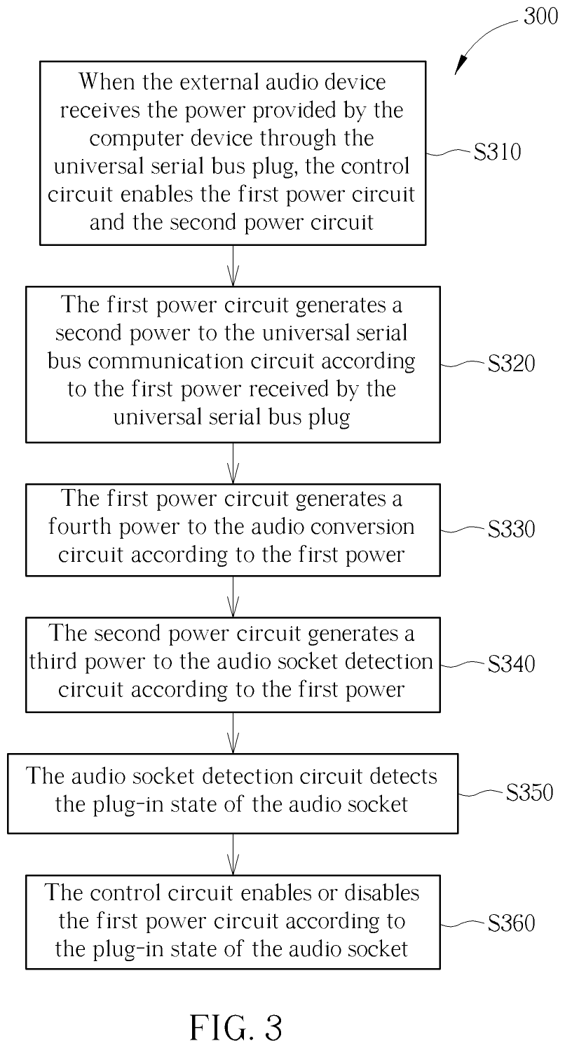

FIG. 3 is a method 300 of operating the external audio device 100 according to an embodiment of the present invention. The method 300 may comprise steps S310 to S360.

S310: When the external audio device 100 receives the power provided by the computer device C1 through the universal serial bus plug 110, the control circuit 170 enables the first power circuit 150 and the second power circuit 160;

S320: The first power circuit 150 generates a second power V2 to the universal serial bus communication circuit 130 according to the first power V1 received by the universal serial bus plug 110;

S330: The first power circuit 150 generates a fourth power V4 to the audio conversion circuit 180 according to the first power V1;

S340: The second power circuit 160 generates a third power V3 to the audio socket detection circuit 140 according to the first power V1;

S350: The audio socket detection circuit 140 detects the plug-in state of the audio socket 120;

S360: The control circuit 170 enables or disables the first power circuit 150 according to the plug-in state of the audio socket 120.

In step S310, when the external audio device 100 changes from not being powered on to receiving the first power V1 through the universal serial bus plug 110, the control circuit 170 may first enable the first power circuit 150 and the second power circuit 160. Then, the first power circuit 150 can generate the second power V2 and the fourth power V4 to the universal serial bus communication circuit 130 and the audio conversion circuit 180 according to the first power V1 in steps S320 and S330, and the second power circuit 160, in step S340, can generate the third power source V3 to the audio socket detection circuit 140 according to the first power source V1.

Then, the audio socket detection circuit 140 can detect the plug-in state of the audio socket 120 in step S350, and the control circuit 170 can enable or disable the first power circuit 150 according to the plug-in state of the audio socket 120 in step S360.

For example, when the audio socket detection circuit 140 detects that the audio socket 120 is plugged in, the control circuit 170 can enable the first power circuit 150 so that the universal serial bus communication circuit 130 can establish a connection with the computer device C1. When the audio socket detection circuit 140 detects that the audio socket 120 is not plugged in, the control circuit 170 can disable the first power circuit 150 to cut off the connection.

In this way, it is possible to stop supplying power to the universal serial bus communication circuit 130 and the audio conversion circuit 180 when the audio socket 120 is not coupled to a device such as a headset or a microphone so as to reduce power consumption of the computer device C1.

In some embodiments, the method 300 can also be applied to the external audio device 200. In this case, the audio socket detection circuit 240 will detect the plug-in states of the audio sockets 220A and 220B in step S350, and the control circuit 270 can enable or disable the first power circuit 250 according to the plug-in states of the audio sockets 220A and 220B. For example, when the audio socket detection circuit 240 detects that the audio socket 220A and/or the audio socket 220B is plugged in, the control circuit 270 can enable the first power circuit 250. At this time, the universal serial bus communication circuit 230 and the audio conversion circuit 280 can operate normally. When the audio socket detection circuit 240 detects that the audio sockets 220A and 220B are not plugged in, the control circuit 270 can disable the first power circuit 250. At this time, the universal serial bus communication circuit 230 and the audio conversion circuit 280 will stop functioning.

In addition, to ensure that the audio socket detection circuit 240 can detect the plug-in states of the audio sockets 220A and 220B in real time, the control circuit 270 can keep the second power circuit 260 enabled.

In this way, it is possible to stop supplying power to the universal serial bus communication circuit 230 and the audio conversion circuit 280 when the audio sockets 220A and 220B are not coupled to devices such as headsets or microphones, thereby reducing the power loss of the computer device C1.

In summary, the external audio device and the method for operating the external audio device provided by the embodiments of the present invention can control the internal power circuit according to the plug-in state of the audio socket to reduce unnecessary power loss. For example, when the audio socket is plugged in, the control circuit can enable the power circuit of the universal serial bus communication circuit and the audio conversion circuit to enable normal operation. When the audio socket is not plugged in, the control circuit can disable the power circuit of the universal serial bus communication circuit and the audio conversion circuit to reduce the power consumption of the computer device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An external audio device comprising:
a USB (Universal Serial Bus) plug configured to couple with a computer device;
a first audio socket configured to couple to a headset or a microphone;
a USB communication circuit configured to establish a connection with the computer device according to a USB communication protocol;
an audio socket detection circuit configured to detect a plug-in state of the first audio socket;
a first power circuit configured to generate a second power to the USB communication circuit according to a first power received from the USB plug;
a second power circuit configured to generate a third power to the audio socket detection circuit according to the first power; and
a control circuit configured to enable or disable the first power circuit according to at least the plug-in state of the first audio socket.

2. The external audio device of claim 1 wherein when the external audio device receives the first power through the USB plug, the control circuit enables the first power circuit and the second power circuit.

3. The external audio device of claim 1 wherein:
when the audio socket detection circuit detects that the first audio socket is in a plugged in state, the control circuit enables the first power circuit so that the USB communication circuit establishes the connection with the computer device; and
when the audio socket detection circuit detects that the first audio socket is in an unplugged state, the control circuit disables the first power circuit to cut off the connection.

4. The external audio device of claim 3 wherein:
regardless if the audio socket detection circuit detects that the first audio socket is in the unplugged state or the plugged in state, the control circuit keeps enabling the second power circuit.

5. The external audio device of claim 1 further comprising:
an audio conversion circuit configured to convert a digital audio signal from the computer device into an analog audio signal, and convert an analog audio signal from the microphone into a digital audio signal;
wherein the first power circuit is further used to generate a fourth power to the audio conversion circuit.

6. The external audio device of claim 1 wherein:
the USB plug is a type-C plug regulated by USB.

7. The external audio device of claim 1 further comprising a second audio socket configured to couple to a headset or a microphone wherein:
the audio socket detection circuit is further configured to detect a plug-in state of the second audio socket; and
the control circuit is configured to enable or disable the first power circuit according to the plug-in state of the first audio socket and the plug-in state of the second audio socket.

8. The external audio device of claim 7 wherein:
when the audio socket detection circuit detects that the first audio socket and/or the second audio socket is in a plugged in state, the control circuit enables the first power circuit; and
when the audio socket detection circuit detects that the first audio socket and the second audio socket are in an unplugged state, the control circuit disables the first power circuit.

9. A method of operating an external audio device, the external audio device comprising a USB (Universal Serial Bus) plug, a first audio socket, a USB communication circuit, an audio socket detection circuit, a first power supply circuit, a second power supply circuit, and a control circuit, the method comprising:
the first power circuit generating a second power to the USB communication circuit according to a first power received by the USB plug;
the second power circuit generating a third power to the audio socket detection circuit according to the first power;
the audio socket detection circuit detecting a plug-in state of the first audio socket; and
the control circuit enabling or disabling the first power circuit according to at least the plug-in state of the first audio socket.

10. The method of claim 9 further comprising:
when the external audio device receives power supplied from a computer device to the USB plug, the control circuit enabling the first power circuit and the second power circuit.

11. The method of claim 10 wherein the control circuit enabling or disabling the first power circuit according to at least the plug-in state of the first audio socket comprises:
when the audio socket detection circuit detects that the first audio socket is in a plugged in state, the control circuit enabling the first power circuit so that the USB communication circuit establishes a connection with the computer device; and
when the audio socket detection circuit detects that the first audio socket is in an unplugged state, the control circuit disabling the first power circuit to cut off the connection.

12. The method of claim 10, wherein:
regardless if the audio socket detection circuit detects that the first audio socket is in the unplugged state or the plugged in state, the control circuit keeps enabling the second power circuit.

13. The method of claim 9, wherein the external audio device further comprises an audio conversion circuit, and the method further comprises:
the first power circuit generating a fourth power to the audio conversion circuit according to the first power so that the audio conversion circuit converts a digital audio signal received from a computer device into an analog audio signal or converts an analog audio signal received from a microphone into a digital audio signal.

14. The method of claim 9, wherein:
the USB plug is a type-C plug regulated by USB.

15. The method of claim 9, wherein the external audio device further comprises a second audio socket, and the method further comprises:
the audio socket detection circuit detecting a plug-in state of the second audio socket.

16. The method of claim 15, wherein the control circuit enabling or disabling the first power circuit according to at least the plug-in state of the first audio socket comprises:
when the audio socket detection circuit detects that the first audio socket and/or the second audio socket is in a plugged in state, the control circuit enabling the first power circuit; and
when the audio socket detection circuit detects that the first audio socket and the second audio socket are in an unplugged state, the control circuit disabling the first power circuit.
